(19) United States
(12) Patent Application Publication
(10) Pub. No.: US 2021/0111093 A1
(43) Pub. Date: Apr. 15, 2021

(54) Heterogeneous Lid Seal Band for Structural Stability in Multiple Integrated Circuit (IC) Device Modules

(71) Applicant: International Business Machines Corporation, Armonk, NY (US)

(72) Inventors: Tuhin Sinha, Oradell, NJ (US); Stephanie Allard, St-Hyacinthe (CA); Jean Labonte, Cowansville (CA); Shidong Li, Hopewell Junction, NY (US)

(21) Appl. No.: 16/598,185

(22) Filed: Oct. 10, 2019

(51) Int. Cl. H01L 23/367; H01L 21/48

(52) U.S. Cl. CPC H01L 23/3675; H01L 21/4882

(57) ABSTRACT

An integrated circuit (IC) module includes a carrier and multiple IC devices. A heterogenous seal band connects a lid to the carrier. A perimeter wall of the lid is joined to a low modulus seal band and an inner wall of the lid is joined to a high modulus seal band. The low modulus seal band is located around the perimeter of the lid and a perimeter of the multiple IC devices. The high modulus seal band is located between the multiple IC devices. The low modulus seal band has a low resistance to being deformed elastically and the high modulus seal band has a high resistance to being deformed elastically. The low modulus seal band allows for dimensional fluctuations between the lid and carrier. The high modulus seal band allows for adequate joining of the lid and the carrier with relatively less seal band material.

### FIELD OF THE EMBODIMENTS

Embodiments of the present invention generally relate to electronic devices and more specifically to multiple integrated circuit (IC) device modules that have a heterogenous lid seal band that connects a lid to a carrier.

### DESCRIPTION OF THE RELATED ART

An IC device module may include an integrated circuit (IC) device, such as a chip, die, processor, or the like, packaged onto a carrier. The IC device may be encapsulated by a lid that has high thermal conductivity and is attached to the carrier by a seal band. Flatness of the IC module is important to ensure reliable higher level device packaging. For example, it is important that the carrier be flat to ensure a reliable electrical connection with a system board and it is important that the lid be flat to ensure a reliable thermal connection with a heat spreader, such as a heatsink.

The electronic device that contains the IC package generally operates at an elevated temperature since the energy utilized to power the electronic device is converted to heat. Electronic package warpage may be caused by coefficient of thermal expansion (CTE) mismatches of the various components the package. The mismatched CTE results in the various components expanding and contracting at differing rates.

Known solutions to reduce the package warpage include choosing like CTE materials that make up the electronic package, increasing the thickness or stiffness of the carrier or lid, and decreasing the thickness of the seal band. Choosing like CTE materials to reduce expansion mismatch is limited since the electrical, mechanical or thermal performance of the package should not detrimentally affected by selecting like CTE materials. Increasing the thickness of the carrier or lid usually leads to higher cost and higher stress in other parts of the package such as the IC device contacts electrically connecting the IC device and the carrier, underfill between the IC device and the carrier surrounding the contacts, and thermal interface material (TIM) between the IC device and the lid. Decreasing the thickness of the seal band may be limited because of large openings that exist between the lid and the carrier or because the seal band thickness is already minimized.

### SUMMARY

In an embodiment of the present invention, a method to fabricate an integrated circuit (IC) module is presented. The method includes electrically connecting a first integrated circuit (IC) device and a second IC device to a carrier. The method includes forming a low modulus seal band directly upon the carrier around the perimeter of both the first IC device and the second IC device. The method includes forming a high modulus seal band directly upon the carrier between the first IC device and the second IC device. The method further includes connecting a lid to the carrier by joining a perimeter wall of the lid to the low modulus seal band and by joining an inner wall of the lid to the high modulus seal band.

In another embodiment of the present invention, an integrated circuit (IC) module is presented. The IC module includes a first integrated circuit (IC) device and a second IC device electrically connected to a carrier. The IC module includes a low modulus seal band directly upon the carrier around the perimeter of both the first IC device and the second IC device. The IC module includes a high modulus seal band directly upon the carrier between the first IC device and the second IC device. The IC module further includes a lid connected to the carrier, the lid comprising a perimeter wall joined to the low modulus seal band and inner wall joined to the high modulus seal band.

In another embodiment of the present invention, an electronic system is presented. The electronic system includes a first integrated circuit (IC) device and a second IC device electrically connected to a top surface of a carrier. The electronic system includes a low modulus seal band directly upon the top surface of the carrier around the perimeter of both the first IC device and the second IC device. The electronic system includes a high modulus seal band directly upon the top surface of the carrier between the first IC device and the second IC device. The electronic system includes a lid connected to the top surface of the carrier, the lid comprising a perimeter wall joined to the low modulus seal band and inner wall joined to the high modulus seal band. The electronic system includes a system board electronically connected to a bottom surface of the carrier. The electronic system further includes a heat sink thermally connected to a top surface of the lid.

These and other embodiments, features, aspects, and advantages will become better understood with reference to the following description, appended claims, and accompanying drawings.

### BRIEF DESCRIPTION OF THE FIGURES

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts an electronic system utilizing a prior art IC device module.

FIG. 2 depicts a cross section view of an exemplary IC device module that includes a heterogenous seal band, according to one or more embodiments of the present invention.

FIG. 3 depicts a normal view of an exemplary IC device module that includes a heterogenous seal band, according to one or more embodiments of the present invention.

FIG. 4 and FIG. 5 depict a cross section view of exemplary IC device modules that include a heterogenous seal band, according to one or more embodiments of the present invention.

FIG. 6, FIG. 7, FIG. 8, and FIG. 9 depict a normal view of exemplary IC device modules that include a heterogenous seal band, according to one or more embodiments of the present invention.

FIG. 10 depicts a cross section view of an exemplary IC device module that includes a heterogenous seal band, according to one or more embodiments of the present invention.

FIG. 11 depicts a normal view of an exemplary IC device module that includes a heterogenous seal band, according to one or more embodiments of the present invention.

FIG. 12 depicts an exemplary method of fabricating an IC device module, according to one or more embodiments of the present invention.

FIG. 13 depicts a cross section view of an exemplary electronic system that includes an IC device module that includes a heterogenous seal band, according to one or more embodiments of the present invention.

### DETAILED DESCRIPTION

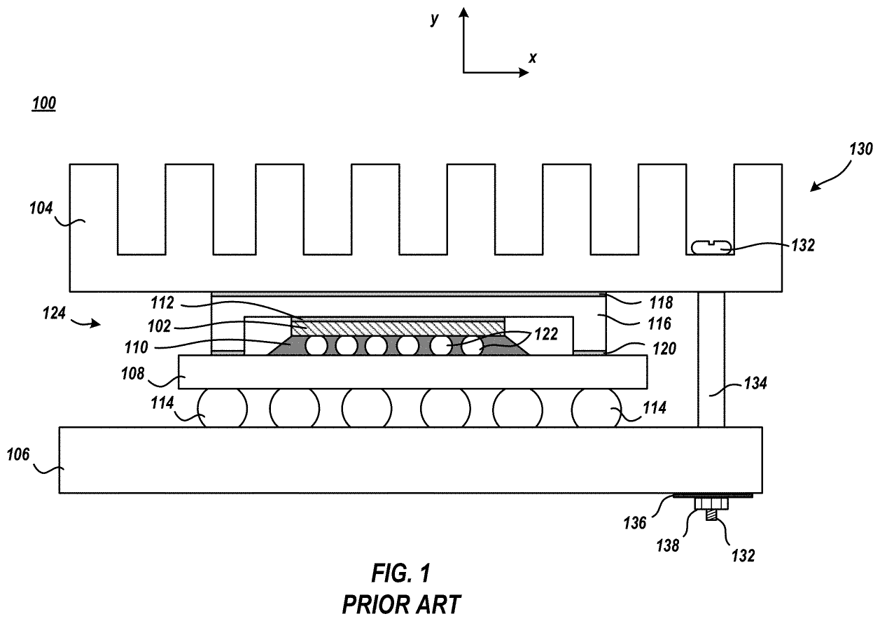

FIG. 1 depicts an electronic system 100 that includes a prior art IC device package 124. Electronic device 100 may be, for example, a computer, server, mobile device, tablet, or the like. Electronic package 124 includes IC device 102, carrier 108, interconnects 122, underfill 110, thermal interface material 112, lid 116, and seal band adhesive 120. IC device 102 may be a semiconductor die, processor, microchip, or the like. Carrier 108 may be an organic carrier or a ceramic carrier and provides mechanical support for IC device 102 and electrical paths from the upper surface of carrier 108 to the opposing side of carrier 108. Interconnects 122 electrically connect IC device 102 and the upper side of carrier 108 and may be a wire bond, solder bond, stud, conductive ball, conductive button, and the like. Underfill 110 may be electrically-insulating, may substantially surround interconnects 122, may electrically isolate individual interconnects 122, and may provide mechanical support between IC device 102 and carrier 108. Underfill 110 may also prevent damage to individual interconnects 122 due to thermal expansion mismatches between IC device 102 and carrier 108.

When IC device 102 is seated upon carrier 108, a reflow process may be performed to join interconnects 122 with respective electrical contacts of IC device 102 and respective electrical contacts of carrier 108. After IC device 102 is joined to carrier 108 a lid 116 is attached to carrier 108 with seal band adhesive 120 to cover IC device 102. Generally, during operation of electronic device 100, heat needs to be removed from IC device 102. In this situation, lid 116 is both a cover and a conduit for heat transfer. As such, a thermal interface material 112 may thermally join lid 116 and IC device 102.

Electronic package 124 may be connected to a system board 106 via interconnects 114. System board 106 may be the main printed circuit board of electronic device 100 and may therefore include other electronic device components, such as a graphics processing unit, memory, hard disk storage, or the like, and may include connectors for other peripheral devices. Interconnects 114 electrically connect the lower side of carrier 108 to system board 106 and may be a wire bond, solder bond, stud, conductive ball, conductive button, and the like. Interconnects 114 may be larger and thus more robust than interconnects 122. When electronic package 124 is joined to system board 106 a second reflow process may be performed to join interconnects 114 with respective electrical contacts of carrier 108 and with respective electrical contacts of system board 106.

In another implementation, the electronic package 124 may be electrically connected to the system board 106 via a socket (not shown). In this implementation, the socket includes interconnects and may be soldered or otherwise placed upon system board 106. The electronic package 124 may be subsequently inserted into the socket to establish electrical connection between interconnects 114 and the socket interconnects to provide for electrical communication between the electronic package 124 and the system board 106.

To assist in the removal of heat from IC device 102 a heatsink 104 may be thermally joined to electronic package 124 via thermal interface material 118. Heatsink 104 may be a passive heat exchanger that cools IC device 102 by dissipating heat into the surrounding air. As such, during operation of electronic device 100, a thermal path exists from IC device 102 to heatsink 104 through thermal interface material 112, lid 116, and thermal interface material 118, and the like. Heatsink 104 may be connected to system board 106 via one or more connection device 130. Connection device 130 may include a threaded fastener 132, standoff 134, backside stiffener 136, and fastener 138. Threaded fastener 132 may extend through heatsink 104, standoff 134, and backside stiffener 136 and provides compressive force between heatsink 104 and backside stiffener 136. The length of standoff 134 may be selected to limit the pressure exerted upon electronic package 124 by heatsink 104 created by the compressive forces. Backside stiffener 136 may mechanically support the compressive forces by distributing the forces across a larger area of motherboard 106. In other applications, connection device 130 may be a clamp, non-influencing fastener, cam, and the like, system that adequately forces heatsink 104 upon electronic package 124.

Thermally connected, joined, and the like, shall herein mean that elements that which are thermally connected are able to efficiently transfer heat there between (e.g., air gaps between the elements are minimized). In some instances, elements that are thermally connected are not directly in physical contact with each other, but rather, are indirectly in contact with each via a thermal interface material. In other instances, elements that are thermally connected are in physical contact with each other. Electrically connected, and the like, shall herein mean that current is able to be efficiently passed from one element to another element (e.g., current flows from a conductor in one element to a conductor in the other element).

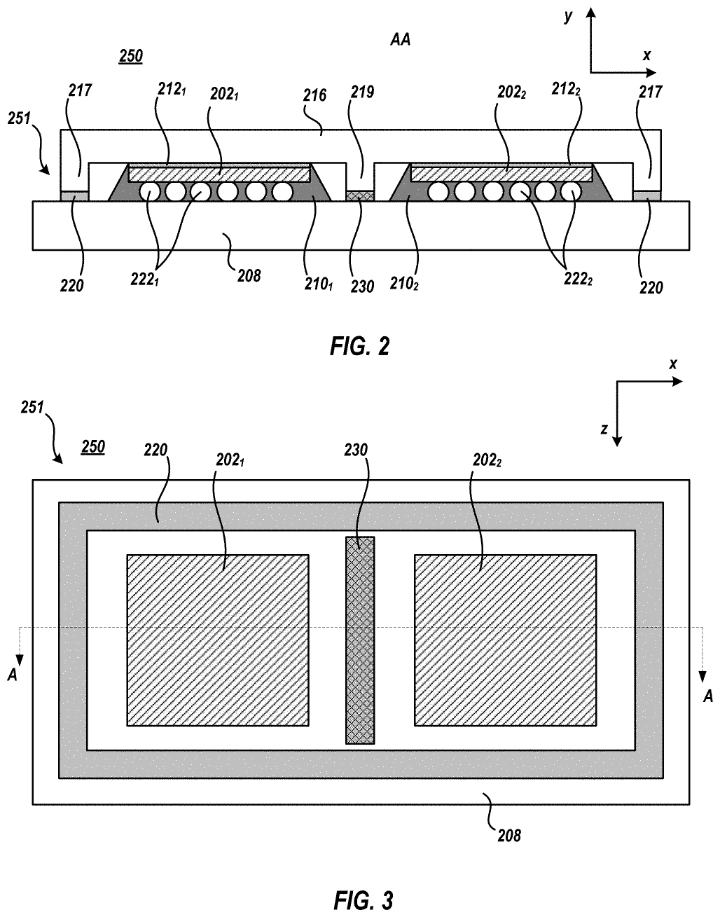

FIG. 2 and FIG. 3. depict various views of an IC device module 250 that includes a heterogenous seal band 251. In embodiments, IC device module 250 further include IC device 202₁, IC device 202₂, carrier 208, interconnects 222₁, interconnects 222₂, underfill 210₁, underfill 210₂, thermal interface material (TIM) 212₁, TIM 212₂, and lid 216.

IC device 202₁ and IC device 202₂ may each be a semiconductor die, processor, microchip, application specific integrated circuit (ASIC), field programmable gate array (FPGA), or the like. IC device 202₁ and IC device 202₂ may be the same or different relative IC devices, may be the same or different normal shape, may have the same or different dimensions, etc.

Carrier 208 may be an organic carrier, ceramic carrier, or the like, and provides mechanical support for IC device 202₁ and IC device 202₂ and electrical paths from the upper surface of carrier 208 to the opposing side of carrier 208. Interconnects 222₁ electrically connect IC device 202₁ and the upper side of carrier 208. For example, an interconnect 222₁ electrically connects a conductive contact or pad of IC device 202₁ and a conductive contact or pad upon the upper side of carrier 208. Interconnects 222₂ electrically connect IC device 202₂ and the upper side of carrier 208. For example, an interconnect 222₂ electrically connects a conductive contact or pad of IC device 202₂ and a conductive contact or pad upon the upper side of carrier 208. Each interconnect 222 electrically connects a wiring line within IC device 202 with a wiring line within carrier 208. The interconnects 222 are conductive and may be a wire bond, solder bond, stud, ball, button, or the like. When IC device 202₁ and IC device 202₂ are seated upon carrier 108, a reflow process may be performed to join interconnects 222₁ and interconnects 222₂ with respective electrical contacts or pads of IC device 202₁ and IC device 202₂ and respective electrical contacts or pads of carrier 108.

Underfill 210₁ may be electrically-insulating, may substantially surround interconnects 222₁, may electrically isolate individual interconnects 222₁, and may provide mechanical support between IC device 202₁ and carrier 108. Underfill 210₁ may also prevent damage to individual interconnects 222₁ due to thermal expansion mismatches between IC device 202₁ and carrier 108. Underfill 210₂ may be electrically-insulating, may substantially surround interconnects 222₂, may electrically isolate individual interconnects 222₂, and may provide mechanical support between IC device 202₂ and carrier 108. Underfill 210₂ may also prevent damage to individual interconnects 222₂ due to thermal expansion mismatches between IC device 202₂ and carrier 108.

Heterogenous seal band 251 includes a low modulus seal band 220 and high modulus seal band 230. Low modulus seal band 220 is a seal band material that, when cured, has a low elastic modulus. The modulus may be in the range of 1 to 50 MegaPascals (MPa) and preferable between 5 to 10 MPa. High modulus seal band 230 is a seal band material that, when cured, has an elastic modulus one order of magnitude higher than the low modulus seal band 220. High modulus seal band 230 may have a modulus in the range of 1-10 GigaPascals (GPa) and preferably in the range of 3-7 GPa.

Heterogenous seal band 251 generally connects or joins the lid 216 with carrier 208. Low modulus seal band 220 is generally associated with connecting an bottom surface of perimeter wall 217 of lid 216 with carrier 208. High modulus seal band 230 is generally associated with connecting the bottom surface of an inner lid wall 219, configured to be located between IC device 202₁ and IC device 202₂, with carrier 208.

Due to the relative difference in the respective elastic modulus, low modulus seal band 220 is more amenable to being deformed elastically relative to high modulus seal band 230 and better absorbs or allows deformation or dimensional changes between carrier 208 and the perimeter or circumference of lid 216 without failure, cracking, or the like of low modulus seal band 220 material. Further, the higher bonding strength provided by high modulus seal band 230 and carrier 208 allows for a relative smaller amount of high modulus seal band 230 material to achieve adequate bonding, thereby allows for IC device 202₁ and IC device 202₂ to be able to be positioned closer together. As such, a relatively increased amount of IC device functionally may be packaged into a smaller area.

Low modulus seal band 220 and high modulus seal band 230 may consist of or otherwise include polymers that when cured result in hardening of the seal band material due to polymer cross-linking. Low modulus seal band 220 may be, for example, a weakly cross-linked polymer compound, elastomeric, or the like. High modulus seal band 230 may be, for example, an epoxy, adhesive, or the like.

In some instances, high modulus seal band 230 may have a higher thermal conductivity or heat transfer coefficient relative to the thermal conductivity or heat transfer coefficient of low modulus seal band 220 to better transfer heat away from the higher temperature region between IC device 202₁ and IC device 202₂. In certain instances, one or both of the high modulus seal band 230 and low modulus seal band 220 may be electrically conductive to allow electrical grounding of a conductive lid 216 to the carrier 208.

Lid 216 covers and encapsulates IC device 202₁ and IC device 202₂. Lid 216 may be fabricated from a material with high thermal conductivity or high heat transfer coefficient. For example, lid 216 may be formed from a metal, such as copper, etc.

Lid 216 may include a generally horizontal parallel plate with perimeter wall 217 extending from the lower surface at the perimeter or circumference thereof and inner wall 219 extending from the lower surface at interior location(s) corresponding to the location(s) between IC devices 202. Perimeter wall 217 and inner wall 219 may each have parallel opposing sidewalls that are coplanar with the parallel plate.

During operation of the electronic system in which IC device module 250 is apart, heat needs to be removed from IC device 202₁ and IC device 202₂. In this situation, lid 216 is both a cover and a conduit for heat transfer. As such, a thermal interface material 212₁ and thermal interface material 212₂ may thermally connect lid 216 and IC device 202₁ and IC device 202₂, respectively.

Heterogenous seal band 251 may be applied upon the carrier 208 or to lid 216 prior to lid 216 being thermally connected to IC devices 202. Low modulus seal band 220 is generally applied around the perimeter of IC devices 202. Therefore, low modulus seal band 220 may have a similar perimeter shape relative to lid 216. For example, if lid 216 has a square normal perimeter shape low modulus seal band 220 also has a square normal perimeter shape, if lid 216 has a hexagon perimeter shape low modulus seal band 220 also has a hexagon perimeter shape. Seal band 251 may be applied to the carrier 208 such that IC devices 202 are located internal to low modulus seal band 220 with low modulus seal band 220 completely surrounding the IC devices 202. Heterogenous seal band 251 may be applied by first applying a ring of low modulus seal band 220 and subsequently applying a pattern of high modulus seal band 230, or vice versa.

The deformation properties of heterogenous seal band 251 may allow for dimensional fluctuations between the perimeter wall 219 of lid 216 and carrier 208 without cracking or other failure, while high modulus seal band 230 provides the rigidity to adequately or firmly couple lid 216 and carrier 208 where dimensional fluctuations may not be as great.

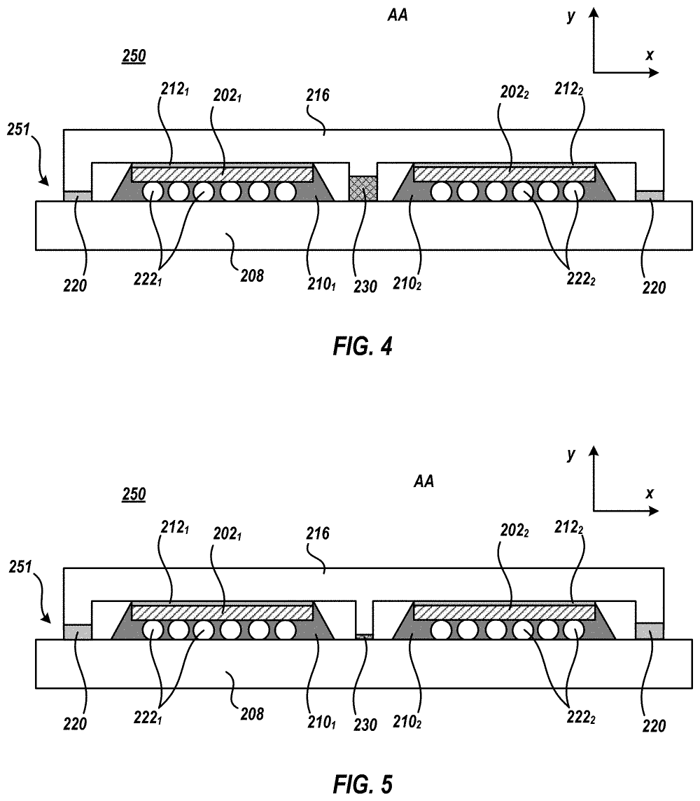

FIG. 4 and FIG. 5 depict a cross section view of exemplary IC device module 250 that include a heterogenous seal band 251, according to one or more embodiments of the present invention. FIG. 4 depicts IC device module 250 where high modulus seal band 230 is formed or is otherwise thicker than low modulus seal band 220. In other words, the top surface of high modulus seal band 230 is higher or above (e.g., greater y-axis value as depicted, etc.) relative to the top surface of low modulus seal band 220. A relatively thicker high modulus seal band 230 generally reduces the stress in the heterogenous seal band 251 but may also cause a moderate increase in TIM 212 strain.

FIG. 5 depicts IC device module 250 where high modulus seal band 230 is formed or is otherwise thinner than low modulus seal band 220. In other words, the top surface of high modulus seal band 230 is lower or below (e.g., smaller y-axis value as depicted, etc.) relative to the top surface of low modulus seal band 220. A relatively thinner high modulus seal band 230 generally reduces TIM 212 strain but may also cause a moderate stress increase in heterogenous seal band 251.

The thickness or thinness of high modulus seal band 230 relative to low modulus seal band 220 may be dictated upon the needs of the package and layout of other components on the package such as capacitors, memory, CSPs, etc.

In some embodiments the width in the x-axis of high modulus seal band 230 may be less than the width in the x-axis of low modulus seal band 220. In such implementations, due to the increased rigidity and bonding properties of high modulus seal band 230, less high modulus seal band 230 material may be needed to adequately join lid 216 to carrier 208. Therefore, the IC devices 220 may be packaged relatively closer together.

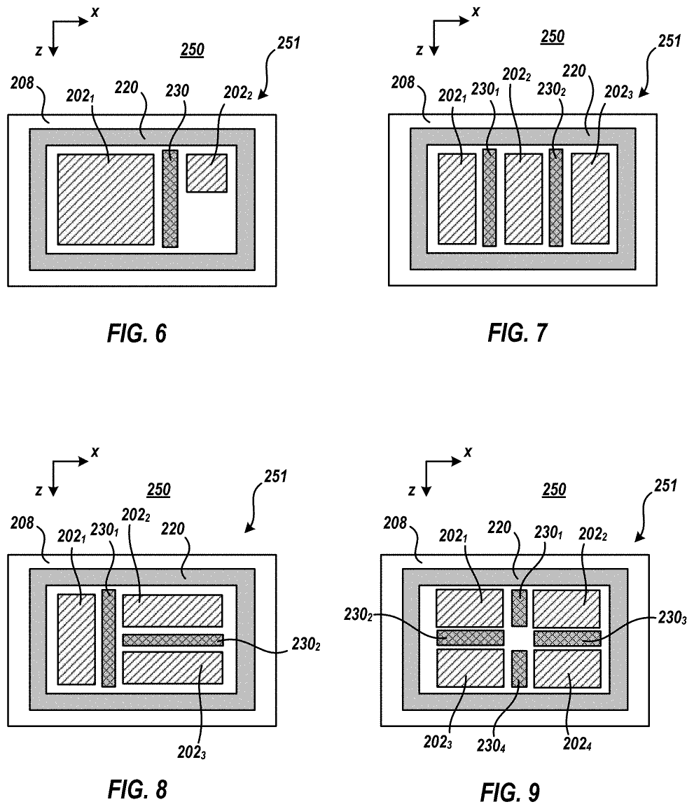

FIG. 6, FIG. 7, FIG. 8, and FIG. 9 depict normal views of IC device module 250 with cover 216 removed, to better show different implementations of the present invention. FIG. 6 depicts IC device module 250 that includes heterogenous seal band 251. In the depicted implementation, high modulus seal band 230 is between relatively different IC device 202₁ and IC device 202₂ and low modulus seal band 220 is around the perimeter of relatively different IC device 202₁ and IC device 202₂. High modulus seal band 230 is internal to the low modulus seal band 220 perimeter.

FIG. 7 depicts IC device module 250 that includes heterogenous seal band 251. In the depicted implementation, high modulus seal band 230₁ is between IC device 202₁ and IC device 202₂ and high modulus seal band 230₂ is between IC device 202₂ and IC device 202₃. Low modulus seal band 220 is around the perimeter of IC device 202₁, IC device 202₂, and IC device 202₃. High modulus seal band 230₁ and high modulus seal band 230₂ are internal to the low modulus seal band 220 perimeter. The front and/or rear surfaces of high modulus seal band 230₁ and/or high modulus seal band 230₂ may be coplanar with the front and/or rear walls or surfaces of IC device 202₁, IC device 202₂, and/or IC device 202₃, respectively. Alternatively, and as depicted by 230₁, the front and/or rear surfaces of high modulus seal band 230₁ and/or high modulus seal band 230₂ may extend beyond the front and/or rear walls or surfaces of IC device 202₁, IC device 202₂, and/or IC device 202₃, respectively. Alternatively, as depicted by 230₂, the front and/or rear surfaces of high modulus seal band 230₁ and/or high modulus seal band 230₂ may be inset from the front and/or rear walls or surfaces of IC device 202₁, IC device 202₂, and/or IC device 202₃, respectively.

High modulus seal band 230₁ and high modulus seal band 230₂ may have the same orientation. Similarly, high modulus seal band 230₁ and high modulus seal band 230₂ may have the same relative length. For example, high modulus seal band 230₁ and high modulus seal band 230₂ may be generally parallel with the z axis and have the same or substantially similar length.

FIG. 8 depicts IC device module 250 that includes heterogenous seal band 251. In the depicted implementation, high modulus seal band 230₁ is between IC device 202₁ and both IC device 202₂ and IC device 202₃. High modulus seal band 230₂ is between IC device 202₂ and IC device 202₃. Low modulus seal band 220 is around the perimeter of IC device 202₁, IC device 202₂, and IC device 202₃. High modulus seal band 230₁ and high modulus seal band 230₂ are internal to the low modulus seal band 220 perimeter. The left and right side surfaces of high modulus seal band 230₁ and/or high modulus seal band 230₂ may be coplanar with the left and right walls or surfaces of IC device 202₁, IC device 202₂, and/or IC device 202₃, respectively. For example, and as depicted, the left and right surfaces of high modulus seal band 230₂ may be coplanar with the left and right walls or surfaces of IC device 202₂ and/or IC device 202₃.

High modulus seal band 230₁ and high modulus seal band 230₂ may have a different orientation. Similarly, high modulus seal band 230₁ and high modulus seal band 230₂ may have different lengths. For example, high modulus seal band 230₁ may be generally parallel with the z axis and shorter in length relative to high modulus seal band 230₂ that may be generally parallel with the x axis.

FIG. 9 depicts IC device module 250 that includes heterogenous seal band 251. In the depicted implementation, high modulus seal band 230₁ is between IC device 202₁ and IC device 202₂. High modulus seal band 230₂ is between IC device 202₁ and IC device 202₃. High modulus seal band 230₃ is between IC device 202₂ and IC device 202₄. High modulus seal band 230₄ is between IC device 202₃ and IC device 202₄. Low modulus seal band 220 is around the perimeter of IC device 202₁, IC device 202₂, IC device 202₃, and IC device 202₃. High modulus seal band 230₁, high modulus seal band 230₂, high modulus seal band 230₃, and high modulus seal band 230₄ are internal to the low modulus seal band 220 perimeter.

The left, right, front, or rear side surfaces of high modulus seal band 230 may be coplanar with the a similar facing surfaces of the neighboring IC devices 202. For example, the left and right surfaces of high modulus seal band 230₂ may be coplanar with the left and right walls or surfaces of IC device 202₁ and/or IC device 202₃, the front and rear surfaces of high modulus seal band 230₁ may be coplanar with the front and rear walls or surfaces of IC device 202₁ and/or IC device 202₂.

In an alternative implementation to that depicted in FIG. 9, a single high modulus seal band 230 may between more than a pair of IC devices 202. For example, high modulus seal band 230₂ could extend from the left side walls of IC device 202₁ and IC device 202₃ to the right side walls of IC device 202₂ and IC device 202₄ or high modulus seal band 230₁ could extend from the rear side walls of IC device 202₁ and IC device 202₂ to the front side walls of IC device 202₃ and IC device 202₄.

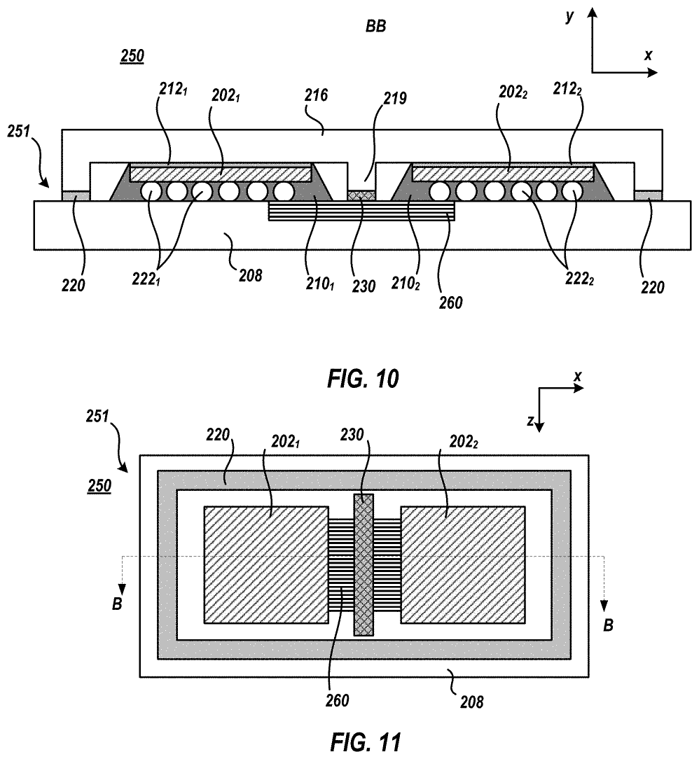

FIG. 10 depicts a cross section view and FIG. 11 depicts a cross section view of IC device module 250 that includes heterogenous seal band 251 that is partially formed or is at least partially upon a bridge 260, according to one or more embodiments of the present invention.

Bridge 260 may be an input/output bridge that may electrically connect IC device 202₁ and IC device 202₂. Bridge 260 may be a glass, substrate, laminate, organic material (e.g., Silicon, etc.) based structure that includes electrically insulating or dielectric material that surrounds electrical paths therein. Bridge 260 may include a single or multiple electrical path levels and includes an IC device facing surface that may include conductive contacts or pads. These conductive features are associated with I/O or other current transfer between two different IC devices 202 and may be connected to electrical paths that exist within the interconnected IC devices 202. The IC device facing surface may be coplanar with the top surface of carrier 208. In other words, bridge 260 may be inset within a cutout or other similar feature of carrier 208. Each IC device 202 may be mounted or otherwise electrically joined to carrier 208 and bridge 260 simultaneously by interconnects 222. For example, interconnects 222₁ may join IC device 202₁ and carrier 208 while another set of interconnects 222₁ may join IC device 202₁ and bridge 260, interconnects 222₂ may join IC device 202₂ and carrier 208 while another set of interconnects 222₂ may join IC device 202₂ and bridge 260. Bridge 260 may be connected within the cutout of carrier 208 by an adhesive, epoxy, or the like.

In the depicted embodiment, high modulus seal band 230 is generally associated with connecting the bottom surface of an inner lid wall 219, configured to be located between IC device 202₁ and IC device 202₂, with carrier 208 and with bridge 260. The higher bonding strength provided by high modulus seal band 230 and carrier 208 and high modulus seal band 230 and bridge 260 allows for a relative smaller amount of high modulus seal band 230 material to achieve adequate bonding, thereby allows for IC device 202₁ and IC device 202₂ to be able to be positioned closer together. As such, a relatively increased amount of IC device functionally may be packaged into a smaller area. In the depicted embodiment, heterogenous seal band 251 may be applied upon the carrier 208 and upon the bridge 260 or to lid 216 prior to lid 216 being thermally connected to IC devices 202.

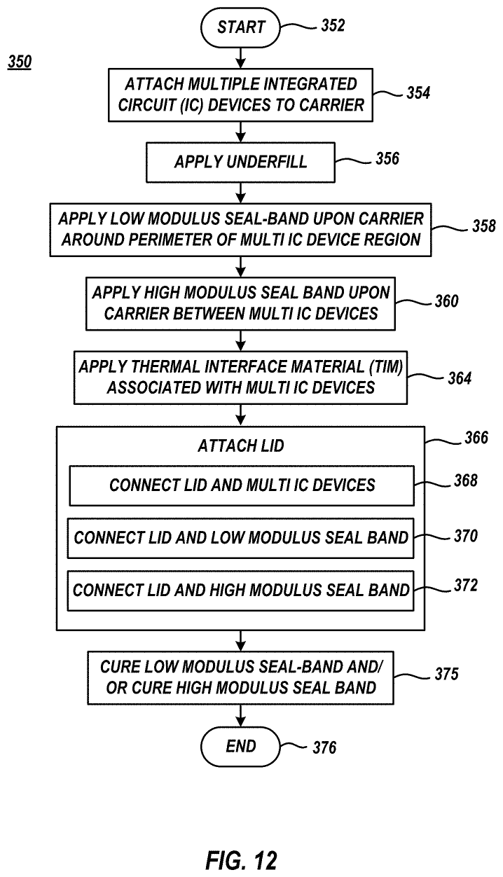

FIG. 12 depicts an exemplary method 350 of fabricating an IC device module 250, according to one or more embodiments of the present invention. Method 350 may begin at block 352 and continue with attaching or otherwise joining multiple IC devices 202 to carrier 208 (block 354). For example, an interconnect 222₁ electrically connects a contact pad of IC device 202₁ and a contact pad that is upon the upper surface of carrier 208, an interconnect 222₂ electrically connects a contact pad of IC device 202₂ and a contact pad that is upon the upper surface of carrier 208. In some implementations, at the present stage of fabrication, the multiple IC devices 202 may be simultaneously joined to bridge 260 as well as to carrier 208. For example, a first interconnect 222₁ may join a first contact pad of IC device 202₁ and a contact pad of carrier 208 while a second interconnect 222₁ may join a second contact pad of IC device 202₁ and a first contact pad of bridge 260, a first interconnect 222₂ may join a first contact pad of IC device 202₂ and a contact pad of carrier 208 while a second interconnect 222₂ may join a second contact pad of IC device 202₂ and a second contact pad of bridge 260.

When IC device 202₁ and IC device 202₂ are attached, a reflow process may be performed to join interconnects 222₁ and interconnects 222₂ with respective electrical contacts or pads of IC device 202₁ and IC device 202₂ and respective electrical contacts or pads of carrier 108/bridge 260.

Method 350 may continue with forming or applying underfill between the multiple IC devices and carrier 208. For example, underfill 310 material may be applied to the top surface of carrier 208 around the perimeter of each IC device 208. Capillary action may draw the underfill 210 material thereunder. In some implementations, at the present stage of fabrication, the underfill 310 may be formed or applied between the multiple IC devices and carrier 208 and between the multiple IC devices and bridge 260.

Method 350 may continue with applying low modulus seal band 220 around the perimeter of the multiple IC devices 202 (block 358). For example, a low modulus seal band 220 bead may be applied upon the carrier 208 around the perimeter of all of the multiple IC devices 202. Alternatively, or in addition to, low modulus seal band 220 bead may be applied upon the lower or carrier 208 facing surface of perimeter wall 217 of lid 216.

Method 350 may continue with applying high modulus seal band 230 internal to the low modulus seal band 220 between the multiple IC devices (block 360). For example, a high modulus seal band 230 bead may be applied upon the carrier 208 internal to the low modulus seal band 220 boundary and between the multiple IC devices 202. Alternatively, or in addition to, high modulus seal band 230 may be applied upon the lower or carrier 208 facing surface of inner lid wall 219 of lid 216.

Method 350 may continue with applying or forming TIM 212 between each of the multiple IC devices 202 and the underside of lid 216 (block 364). For example, TIM 212 may be applied to the top surface of each of the multiple devices 202 or alternatively, or in addition to, may be applied to the underside of lid 216 in locations that align with each of the IC devices 202.

Method 350 may continue with attaching lid 216 (block 366). For example, the lid 216 may be connected to each of the multiple IC devices 216 such that the TIM 212 simultaneously contacts the underside of lid 216 and the upper surface of each of the IC devices 202 (block 368). Further, for example, the lid 216 may be connected to carrier 208 such that low modulus seal band 220 simultaneously contacts the underside of perimeter wall 217 of lid 216 and the upper surface of carrier 208 (block 370). Further, for example, the lid 216 may be connected to carrier 208 such that high modulus seal band 230 simultaneously contacts the underside of inner wall 219 of lid 216 and the upper surface of carrier 208.

Method 350 may continue with curing the low modulus seal band 220 and high modulus seal band 230 (block 375). Low modulus seal band 220 and high modulus seal band 230 may be cured by heating to a sufficient temperature to harden the low modulus seal band 220 and high modulus seal band 230 material due to polymer cross-linking. Upon curing, the low modulus seal band 220 has higher elastomeric or deformation properties or tendencies relative to the high modulus seal band 230. Upon curing, the low modulus seal band 220 joins the perimeter wall 217 of lid 216 and the upper surface of carrier 208 and the high modulus seal band 230 joins the inner wall 219 of lid 216 and the upper surface of carrier 208/bridge 260. Method 350 may end at block 376.

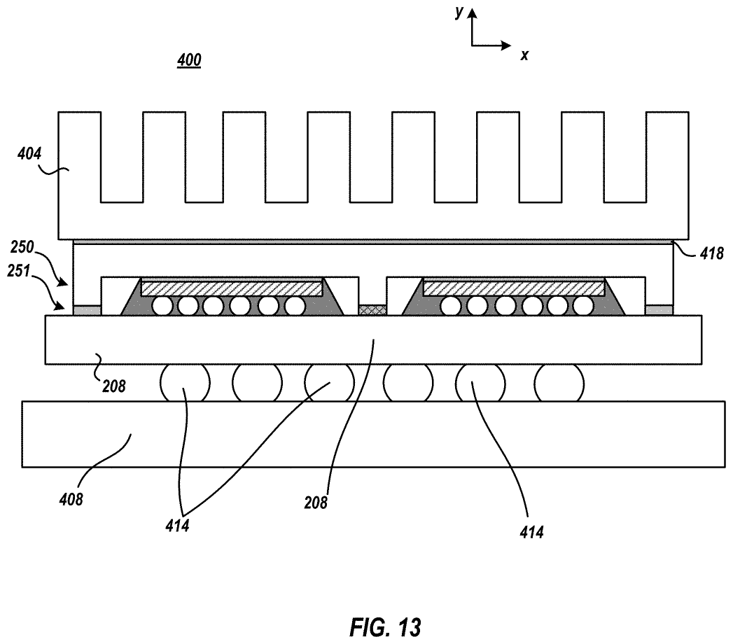

FIG. 13 depicts a cross section view of an exemplary electronic system 400 that includes IC device module 250 that includes heterogenous seal band 251, according to one or more embodiments of the present invention. Electronic system 400 may be, for example, a computer, server, mobile device, tablet, cash machine, kiosk, or the like.

IC device module 250 may be connected to a system board 408 via interconnects 414. System board 408 may be the main printed circuit board of electronic device 400 and may therefore include other electronic device components, such as a graphics processing unit, memory, hard disk storage, or the like, and may include connectors for other peripheral devices. Interconnects 414 electrically connect the lower side of carrier 208 to the upper surface of system board 408 and may be a wire bond, solder bond, stud, conductive ball, conductive button, and the like. Interconnects 414 may be larger and thus more robust than interconnects 222. IC device module 250 is joined to system board 408 a second reflow process may be performed to join interconnects 414 with respective electrical contacts or pads upon the lower surface of carrier 208 and with respective electrical contacts or pads upon the upper surface of system board 408.

In another implementation, IC device module 250 may be electrically connected to the system board 408 via a socket (not shown). In this implementation, the socket includes interconnects and may be soldered or otherwise placed upon system board 408. IC device module 250 may be subsequently inserted into the socket to establish electrical connection between interconnects 414 and the socket interconnects to provide for electrical communication between the IC device module 250 and the system board 408.

To assist in the removal of heat from IC devices 202 a heatsink 404 may be thermally joined to IC device module 250 via thermal interface material 418. Heatsink 404 may be a passive heat exchanger that cools IC devices 202 by dissipating heat into the surrounding air or may be an active heat exchanger that cools IC devices 202 by dissipating heat into an actively cooled fluid. As such, during operation of electronic device 400, a thermal path exists from IC devices 202 to heatsink 404 through lid 116, through thermal interface material 418, and into heat sink 404, etc.

The accompanying figures and this description depicted and described embodiments of the present invention, and features and components thereof. Those skilled in the art will appreciate that any particular program nomenclature used in this description was merely for convenience, and thus the invention should not be limited to use solely in any specific application identified and/or implied by such nomenclature.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

References herein to terms such as “vertical”, “horizontal”, and the like, are made by way of example, and not by way of limitation, to establish a frame of reference. The term “horizontal” as used herein is defined as a plane parallel to the conventional plane or surface of the carrier 208, regardless of the actual spatial orientation of the carrier 208. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

What is claimed is:

1. A method to fabricate an integrated circuit (IC) module comprising:
electrically connecting a first integrated circuit (IC) device and a second IC device to a carrier;
forming a low modulus seal band directly upon the carrier around the perimeter of both the first IC device and the second IC device;
forming a high modulus seal band directly upon the carrier between the first IC device and the second IC device; and
connecting a lid to the carrier by joining a perimeter wall of the lid to the low modulus seal band and by joining an inner wall of the lid to the high modulus seal band.

2. The method of claim 1, wherein connecting the lid to the carrier further comprises curing the low modulus seal band and curing the high modulus seal band.

3. The method of claim 2, wherein upon curing of the low modulus seal band and curing of the high modulus seal band, the high modulus seal band has an elastic modulus at least one order of magnitude higher than an elastic modulus of the low modulus seal band.

4. The method of claim 1, wherein an upper surface of the high modulus seal band is coplanar with an upper surface of the low modulus seal band.

5. The method of claim 1, wherein an upper surface of the high modulus seal band is lower than an upper surface of the low modulus seal band.

6. The method of claim 1, wherein a width between opposing side surfaces of the high modulus seal band is less than a width between opposing side surfaces of the low modulus seal band.

7. The method of claim 1, wherein a front surface of the high modulus seal band is coplanar with a front surface of the first IC device and coplanar with a front surface of the second IC device and wherein a rear surface of the high modulus seal band is coplanar with a rear surface of the first IC device and coplanar with a rear surface of the second IC device.

8. The method of claim 1, wherein a front surface of the high modulus seal band is inset from a front surface of the first IC device and inset from a front surface of the second IC device and wherein a rear surface of the high modulus is inset from a rear surface of the first IC device and inset from a rear surface of the second IC device.

9. An integrated circuit (IC) module comprising:
a first integrated circuit (IC) device and a second IC device electrically connected to a carrier;
a low modulus seal band directly upon the carrier around the perimeter of both the first IC device and the second IC device;
a high modulus seal band directly upon the carrier between the first IC device and the second IC device; and
a lid connected to the carrier, the lid comprising a perimeter wall joined to the low modulus seal band and inner wall joined to the high modulus seal band.

10. The IC module of claim 9, wherein the high modulus seal band has an elastic modulus at least one order of magnitude higher than an elastic modulus of the low modulus seal band.

11. The IC module of claim 9, wherein an upper surface of the high modulus seal band is coplanar with an upper surface of the low modulus seal band.

12. The IC module of claim 9, wherein an upper surface of the high modulus seal band is lower than an upper surface of the low modulus seal band.

13. The IC module of claim 9, wherein a width between opposing side surfaces of the high modulus seal band is less than a width between opposing side surfaces of the low modulus seal band.

14. The IC module of claim 9, wherein a front surface of the high modulus seal band is coplanar with a front surface of the first IC device and coplanar with a front surface of the second IC device and wherein a rear surface of the high modulus seal band is coplanar with a rear surface of the first IC device and coplanar with a rear surface of the second IC device.

15. The IC module of claim 9, wherein a front surface of the high modulus seal band is inset from a front surface of the first IC device and inset from a front surface of the second IC device and wherein a rear surface of the high modulus is inset from a rear surface of the first IC device and inset from a rear surface of the second IC device.

16. An electronic system comprising:
a first integrated circuit (IC) device and a second IC device electrically connected to a top surface of a carrier;
a low modulus seal band directly upon the top surface of the carrier around the perimeter of both the first IC device and the second IC device;
a high modulus seal band directly upon the top surface of the carrier between the first IC device and the second IC device;
a lid connected to the top surface of the carrier, the lid comprising a perimeter wall joined to the low modulus seal band and inner wall joined to the high modulus seal band;
a system board electronically connected to a bottom surface of the carrier; and
a heat sink thermally connected to a top surface of the lid.

17. The electronic system of claim 16, wherein the high modulus seal band has an elastic modulus at least one order of magnitude higher than an elastic modulus of the low modulus seal band.

18. The electronic system of claim 16, wherein an upper surface of the high modulus seal band is coplanar with an upper surface of the low modulus seal band.

19. The electronic system of claim 16, wherein an upper surface of the high modulus seal band is lower than an upper surface of the low modulus seal band.

20. The electronic system of claim 16, wherein a width between opposing side surfaces of the high modulus seal band is less than a width between opposing side surfaces of the low modulus seal band.
